(19) United States
(12) Patent Application Publication
(10) Pub. No.: US 2009/0170034 A1
(43) Pub. Date: Jul. 2, 2009

(54) METHOD FOR MANUFACTURING SEMICONDUCTOR DEVICE

(75) Inventor: Hee Youl LIM, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/176,938

(22) Filed: Jul. 21, 2008

(30) Foreign Application Priority Data
Dec. 31, 2007 (KR) 10-2007-0141511

(51) Int. Cl. G03F 7/20; H01L 21/306

(52) U.S. Cl. 430/313; 438/738; 257/E21.215

(57) ABSTRACT

A method for manufacturing a semiconductor device comprises: forming a first photoresist pattern in a double patterning technology (DPT) for overcoming a resolution limit of an exposer; and forming a second photoresist pattern. The method further comprises forming a hard mask film and an anti-reflective film to prevent an intermixing phenomenon generated when the second photoresist pattern is formed. As a result, yield and reliability of the process can be improved.

### CROSS-REFERENCE TO RELATED APPLICATION

This application is based upon and claims the benefit of priority to Korean Patent Application No. 10-2007-0141511, filed on Dec. 31, 2007, the entire contents of which are incorporated herein by reference.

### BACKGROUND OF THE INVENTION

The present invention relates to a method for manufacturing a semiconductor device, and more particularly, to a manufacturing method for a double patterning technology (DPT) which reduces the number of required layers and steps by using a crosslinked layer. As a result, yield and reliability of the process can be improved.

Due to the miniaturization and increased integration of semiconductor devices, the whole chip area is increased in proportion to an increase in memory capacity, but an area for a cell region pattern of a semiconductor device is reduced.

In order to secure a desired memory capacity, a large number of patterns should be formed in a limited cell region area. A critical dimension (CD) of a pattern is reduced so that the pattern becomes finer.

A lithography process to obtain a pattern having a fine CD is needed.

The lithography process includes: coating a photoresist over a substrate; performing an exposure process on the photoresist with an exposure mask, where a fine pattern is defined using an exposure source having a wavelength of 365 nm, 248 nm, 193 nm and 153 nm; and performing a development process to form a photoresist pattern that defines a fine pattern.

The resolution (R) of the lithography process is determined by a wavelength (λ) of the light source and a numerical aperture (NA) as shown in the equation R=k1×λ/NA. In the above equation, k1 is a constant process number, which has a physical limit, so that it is impossible to reduce this value by a general method in trying to reduce the resolution (R). Instead, a new photoresist material having a high reaction to the short wavelength is required with an exposer using the short wavelength. As a result, it is difficult to form a fine pattern having a CD below the short wavelength.

Therefore, a double patterning technology has been developed to obtain a fine pattern.

FIGS. 1a to 1c are diagrams illustrating a conventional method for manufacturing a semiconductor device.

Referring to FIG. 1a, a hard mask layer 20 is formed over a semiconductor substrate 10. A first etch barrier film 30, a first polysilicon layer 40, a second etch barrier film 50, a second polysilicon layer 60 and a first anti-reflective film 70 are sequentially formed over the hard mask layer 20.

The etch barrier film and the polysilicon layer are each formed twice for the double patterning process. This is required because the first mask of the double patterning process and the photoresist pattern for the second mask of the double patterning process have to be formed on different layers to avoid an intermixing phenomenon. This increases the number of processes.

A first photoresist pattern 80 for the double patterning process is formed is formed over the first anti-reflective film 70.

Referring to FIG. 1b, the first anti-reflective film 70 and the second polysilicon layer 60 are sequentially etched with the first photoresist pattern 80 as a mask, to form a first anti-reflective pattern 75a and a second polysilicon pattern 65a that defines a first mask of the double patterning process.

Referring to FIG. 1c, the first photoresist pattern 80 and the first anti-reflective pattern 75a are removed. A second anti-reflective film 70s is formed over the second etch barrier film 50 and the second polysilicon pattern 65a.

However, in this conventional method, a process for removing the first photoresist pattern 80 and the first anti-reflective pattern 75a is needed, which increases the number of processes. A process for forming the second anti-reflective film 70s also increases the whole process.

A second photoresist pattern 90 that defines a second mask of the double patterning process is formed over the second anti-reflective film 70s.

Referring to FIG. 1d, the second anti-reflective film 70s is etched with the second photoresist pattern 90 as a mask to form a second anti-reflective pattern 75b. The second anti-reflective film 70s is removed to expose the second polysilicon pattern 65a.

Referring to FIG. 1e, the second etch barrier film 50 is etched with the second polysilicon pattern 65a that defines the first mask, and the second photoresist pattern 90 and the second anti-reflective pattern 75b that defines the second mask for the double patterning process, to form a second etch barrier pattern 55 that defines a fine pattern.

Referring to FIG. 1f, after the second photoresist pattern 90 is removed, the first polysilicon layer 40 is etched with the residual patterns 55 and 75b as a mask to form a first polysilicon pattern 45 that defines a fine pattern. As a result, the second polysilicon pattern 65a that defines the first mask is naturally removed.

Referring to FIG. 1g, the second anti-reflective pattern 75b is removed. A process is performed to pattern a first etch barrier film 35, which also removes the second etch barrier pattern 55. As a result, a first etching barrier pattern 35 that defines a fine pattern is formed.

Referring to FIG. 1h, the hard mask layer 20 is etched with the first polysilicon pattern 45 and the first etching barrier pattern 35 as a mask to form a hard mask pattern 25 that defines a fine pattern.

As mentioned above, the conventional method for forming a fine pattern requires a double patterning technology (DPT) to overcome a resolution limit of an exposer. However, the double patterning process includes: forming a first photoresist pattern; and forming a second photoresist pattern. If the first photoresist pattern is combined with the second photoresist pattern, a defective pattern is created. This is called an intermixing phenomenon. In order to prevent the intermixing phenomenon, a hard mask film and an anti-reflective film are further required. As a result, the number of processes is increased and a defect ratio is increased, thereby degrading yield and reliability of the semiconductor device.

### SUMMARY

Various embodiment of the present invention relate to a method for manufacturing a semiconductor device that comprises: irradiating using ultraviolet light after forming a first photoresist pattern; and forming a crosslink layer that serves as a barrier film over the first photoresist pattern, thereby improving yield and reliability of the semiconductor device.

According to an embodiment of the present invention, a method for manufacturing a semiconductor device comprises: forming a hard mask layer over a semiconductor substrate; forming a first photoresist pattern that defines a first mask pattern over the hard mask layer; forming a protective layer over the first photoresist pattern; forming a second photoresist pattern that defines a second mask pattern for forming a pattern between the first photoresist pattern; and etching the hard mask layer with the first and second photoresist patterns as a mask to form a hard mask pattern.

An underlying layer is formed between the semiconductor substrate and the hard mask layer, the underlying layer including one selected from the group consisting of a nitride film, an oxide film, BPSG, PSG, USG, PE-TEOS, polysilicon, tungsten, tungsten silicide, cobalt, cobalt silicide, titanium silicide, aluminum and combinations thereof. The hard mask layer includes one selected from the group consisting of an amorphous carbon (a-C) layer, a polysilicon layer, a SiON film, an oxide film and combinations thereof. The hard mask layer further includes an etching barrier film. The hard mask layer further includes an anti-reflective film over the etching barrier film.

The method may further comprises performing a baking process to form a crosslink layer after irradiating ultraviolet light (e.g., light having wavelength of 10 nm to 400 nm) to the first photoresist pattern. The energy of the ultraviolet light ranges from 10 to 50 mJ. The baking temperature ranges from 100 to 200° C. A post baking process is performed after the baking process. A developing solution is coated over the first photoresist pattern after the baking process.

When the second photoresist pattern is formed, a loss rate of the top portion of the first photoresist pattern is maintained to be 1˜20% of the height of the first photoresist pattern. When the second photoresist pattern is formed, a loss rate of the sidewall of the first photoresist pattern is maintained to be 1˜10% of the height of the first photoresist pattern. The first or second photoresist pattern is formed by an immersion lithography process.

### BRIEF DESCRIPTION OF THE DRAWINGS

FIGS. 1a to 1c are diagrams illustrating a conventional method for manufacturing a semiconductor device.

FIGS. 2a to 2h are diagrams illustrating a method for manufacturing a semiconductor device according to an embodiment of the present invention.

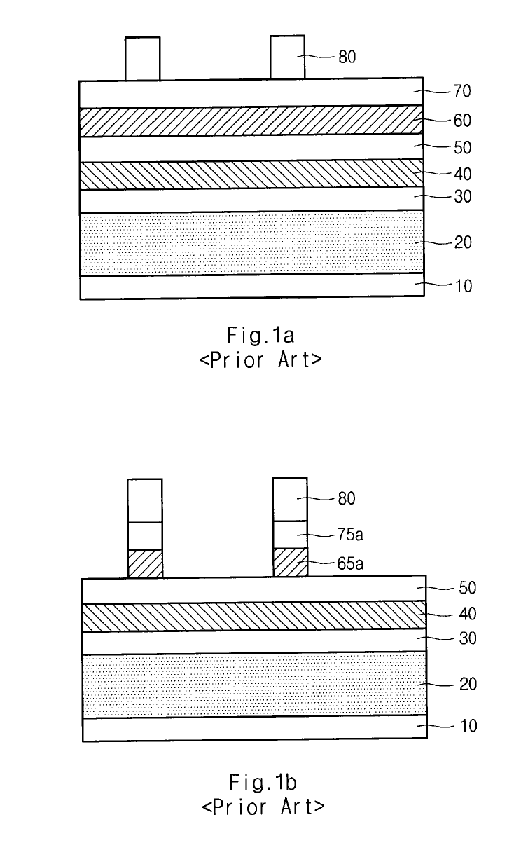

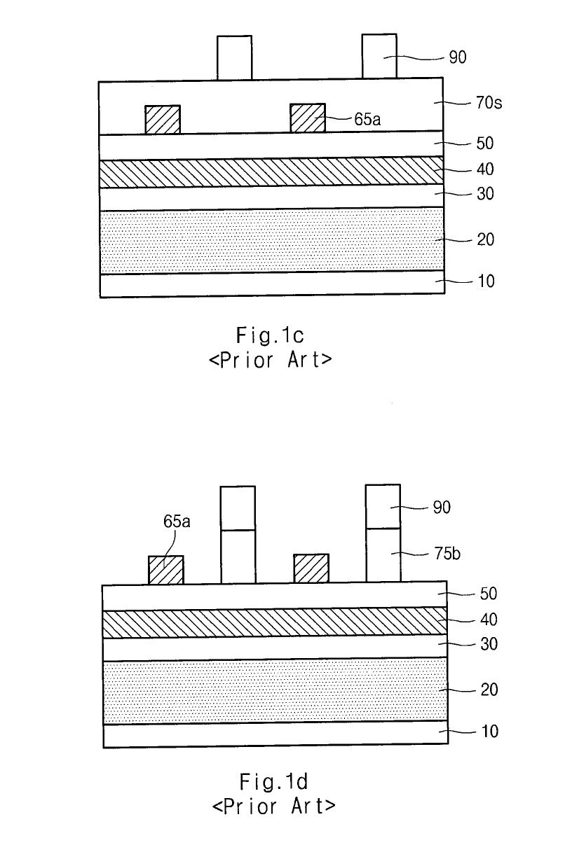

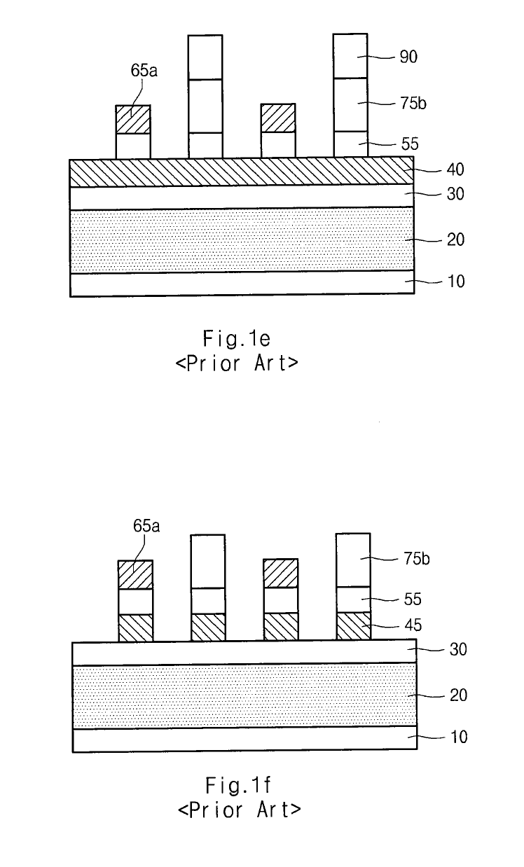

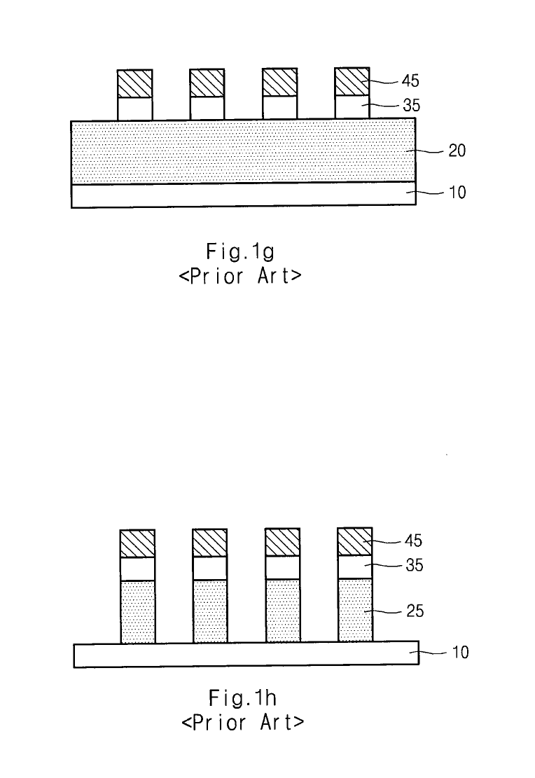

### DETAILED DESCRIPTION

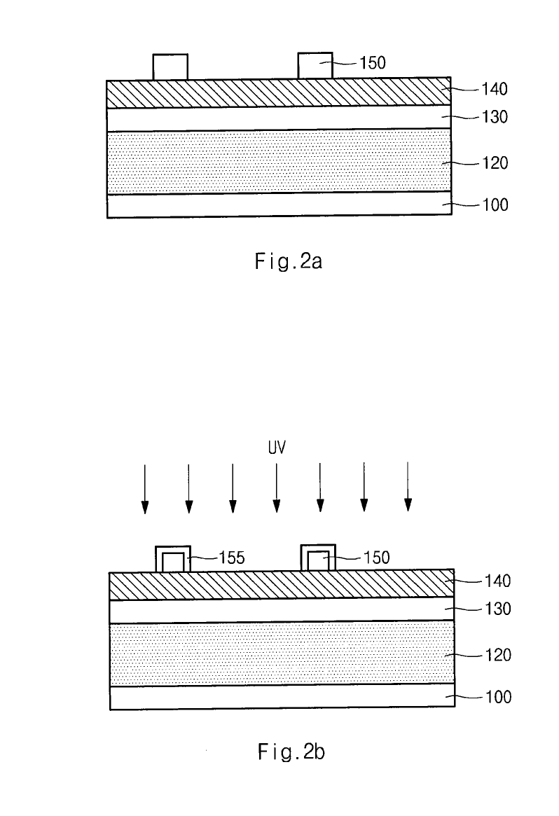

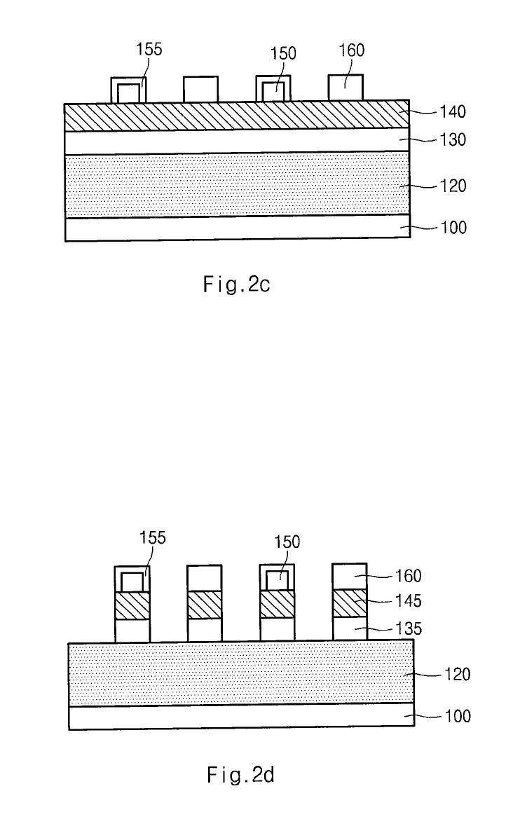

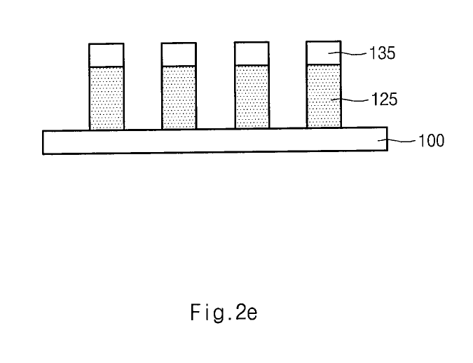

FIGS. 2a to 2h are diagrams illustrating a method for manufacturing a semiconductor device according to an embodiment of the present invention.

Referring to FIG. 2a, an underlying layer (not shown) is formed over a semiconductor substrate 100. A hard mask layer 120, an etching barrier film 130 and an anti-reflective film 140 are sequentially formed over the underlying layer. The underlying layer includes one selected from the group consisting of a nitride film, an oxide film, BPSG, PSG, USG, PE-TEOS, polysilicon, tungsten, tungsten silicide, cobalt, cobalt silicide, titanium silicide, aluminum and combinations thereof, to have a thickness ranging from 200 to 5000 Å.

The hard mask layer 120 includes one selected from the group consisting of an amorphous carbon (a-C) layer, a polysilicon layer, a SiON film, an oxide film and combinations thereof. The etching barrier film 130 includes a silicon oxide nitride (SiON) film. The anti-reflective film 140 has a single-layered or multiple-layered structure including an inorganic or organic anti-reflective film.

A first photoresist pattern 150 is formed over the anti-reflective film 140. The first photoresist pattern 150 includes a plurality of structures/patterns 150 so may be referred to in plural as “the first photoresist patterns.” The first photoresist pattern 150 defines a first mask pattern for a double patterning technology (DPT). Of fine patterns to be formed, a fine pattern having a pitch of 1:3 is defined.

When a first photoresist pattern 150 is formed for an immersion lithography process, a protective film (topcoat, not shown) is formed over the first photoresist pattern 150.

Referring to FIG. 2b, ultraviolet light is irradiated over the first photoresist pattern 150 to form a crosslinked layer 155. After the UV process a baking process is performed to the crosslink layer 155. The ultraviolet light is irradiated using an energy ranging from 10 to 50 mJ and the baking process is performed at a temperature ranging from 100 to 200° C. A post-baking process may be further performed to harden the crosslink layer 155. Instead, a developing solution is coated over the crosslink layer 155 to enhance adhesiveness of the s crosslink layer 155.

When the energy is over 50 mJ, the first photoresist pattern 150 may be damaged. When the energy is below 10 mJ, the crosslink layer may not be formed. As a result, it is important to maintain a proper energy. Also, it is important to maintain the baking temperature within a given range.

The crosslink layer 155 increases resistance to the developing solution so that the first photoresist pattern 150 may not be affected by the developing solution when the second photoresist pattern is formed.

When the immersion lithography process is used, the protective film (topcoat) formed over the first photoresist pattern 150 is removed in a pattern forming process, which does not affect the process for forming the crosslink layer 155 by irradiation of the ultraviolet light.

Referring to FIG. 2c, a second photoresist pattern 160 that defines a second mask pattern for the double pattering process is formed in between the first photoresist patterns 150. The second photoresist patterns 160 includes a plurality of structures/patterns 160 so may be referred to in plural as “the second photoresist patterns.”

The first photoresist pattern 150 is protected from an exposure and development process for forming the second photoresist pattern 160 by the crosslink layer 155. As a result, an additional anti-reflective film is not required like in a conventional art.

However, the crosslink layer 155 does not protect the first photoresist pattern 150 completely. When the second photoresist pattern 160 is formed, a loss rate of the top portion of the first photoresist pattern 150 is regulated by 1˜20% of the whole height of the first photoresist pattern 150. A loss rate of the sidewall of the first photoresist pattern 150 is adjusted by 1˜10% of the critical dimension of the first photoresist pattern 150.

Referring to FIG. 2d, the anti-reflective film 140 and the etching barrier film 130 are etched with the first photoresist pattern 150 including the crosslink layer 155 and the second photoresist pattern 160 as a mask, to form an anti-reflective pattern 145 and an etching barrier pattern 135 that define a fine pattern.

Referring to FIG. 2e, after the crosslink layer 155, the first photoresist pattern 150, the second photoresist pattern 160 and the anti-reflective pattern 145 are removed, the hard mask layer 120 is etched with the etching barrier pattern 135 as a mask to form a hard mask pattern 125 that defines a fine pattern.

The underlying layer (not shown) formed over the semiconductor substrate 100 is etched with the hard mask pattern 125 to obtain a fine pattern.

As described above, according to an embodiment of the present invention, a method for manufacturing a semiconductor device includes performing a double patterning process to overcome a resolution limit of an exposer. Before a second photoresist pattern is formed an ultraviolet light is irradiated over the first photoresist pattern forming a crosslink layer over the first photoresist pattern to prevent damage of the first photoresist pattern. As a result, the polymer crosslink layer has a resistance to a photoresist developing solution, so that several processes for protecting the photoresist pattern can be omitted. In other words, a first hard mask pattern is not required over a hard mask layer, and an anti-reflective film is not formed after the first photoresist pattern is formed. Also, after the first hard mask pattern is formed, an etching process for removing the first photoresist pattern and a strip and cleaning process for removing the first photoresist pattern are not performed, thereby simplifying the process for manufacturing a semiconductor device.

Although a number of illustrative embodiments consistent with the invention have been described, it should be understood that numerous other modifications and embodiments can be devised by those skilled in the art that will fall within the spirit and scope of the principles of this disclosure. More particularly, a number of variations and modifications are possible in the component parts and/or arrangements of the subject combinations arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, the method comprising:
forming a hard mask layer over a semiconductor substrate;
forming first photoresist patterns that define first mask patterns over the hard mask layer;
forming a protective layer over each of the first photoresist patterns;
forming second photoresist patterns that define second mask patterns, each second photoresist pattern being provided between two adjacent first photoresist patterns; and
etching the hard mask layer with the first and second photoresist patterns as a mask to form a hard mask pattern.

2. The method according to claim 1, wherein an underlying layer is formed between the semiconductor substrate and the hard mask layer, the underlying layer including one selected from the group consisting of a nitride film, an oxide film, BPSG, PSG, USG, PE-TEOS, polysilicon, tungsten, tungsten silicide, cobalt, cobalt silicide, titanium silicide, aluminum and combinations thereof.

3. The method according to claim 1, wherein the hard mask layer includes one selected from the group consisting of an amorphous carbon (a-C) layer, a polysilicon layer, a SiON film, an oxide film and combinations thereof.

4. The method according to claim 1, further comprising forming an etch barrier film over the hard mask layer.

5. The method according to claim 1, further comprising forming an anti-reflective film over the etch barrier film.

6. The method according to claim 1, wherein forming the protective layer comprises:
irradiating ultraviolet light to the first photoresist patterns; and
baking the irradiated first photoresist patterns to form a crosslink layer.

7. The method according to claim 6, wherein an energy of the ultraviolet light ranges from 10 to 50 mJ.

8. The method according to claim 6, wherein a baking temperature ranges from 100 to 200° C.

9. The method according to claim 6, wherein a post baking process is performed after the baking process.

10. The method according to claim 6, wherein a developing solution is coated over the first photoresist patterns after the baking process.

11. The method according to claim 1, wherein when the second photoresist patterns are formed, a loss rate of the top portions of the first photoresist patterns are no more than 20% of the height of the first photoresist patterns.

12. The method according to claim 1, wherein when the second photoresist patterns are formed, a loss rate of the sidewall of the first photoresist patterns are no more than 10% of the height of the first photoresist patterns.

13. The method according to claim 1, wherein the first or second photoresist patterns are formed by an immersion lithography process.

14. A method for manufacturing a semiconductor device, the method comprising:
forming a hard mask layer over a semiconductor substrate;
forming a first photoresist pattern over the hard mask layer;
converting an outer portion of the first photoresist pattern to a protective layer;
forming a second photoresist pattern over the hard mask layer and adjacent to the first photoresist pattern having the protective layer; and
etching the hard mask layer with the first and second photoresist patterns as a mask to form a hard mask pattern.

15. The method according to claim 14, wherein the converting step comprises:
irradiating ultraviolet light to the first photoresist pattern; and
baking the irradiated first photoresist pattern to form a crosslink layer.

16. The method according to claim 15, wherein an energy transfer to the first photoresist pattern by the ultraviolet light ranges from 10 to 50 mJ.

17. The method according to claim 15, wherein the baking step is performed in a temperature ranging from 100 to 200° C.
